(19) United States
(12) Patent Application Publication
(10) Pub. No.: US 2005/0236035 A1
(43) Pub. Date: Oct. 27, 2005

(54) High-performance and low-cost plastic solar cells

(76) Inventors: Yang Yang, Los Angeles, CA (US); Fang-Chung Chen, Los Angeles, CA (US)

Correspondence Address: David J Oldenkamp;Shapiro & Dupont, Suite 700, 233 Wilshire Boulevard, Santa Monica, CA, 90401, US

(21) Appl. No.: 10/510,661

(22) PCT Filed: Apr. 16, 2003
(86) PCT No.: PCT/US03/11689

§ 371 Date: May 26, 2005

Related U.S. Application Data
(60) Provisional application No. 60/373,145, filed on Apr. 16, 2002.

(51) Int. Cl. H01L 31/00

(52) U.S. Cl. 136/263; 438/82

(57) ABSTRACT

A solar cell that includes a high efficiency thin film plastic (polymer) as the active material. The active material includes a mixture of a semi-conducting polymer and an ionic electrolyte. The semi-conducting polymer is made up of a ptype polymer and an n-type electron acceptor. The ionic electrolyte is present in said mixture in an amount ranging from 0.01 to 5 weight percent.

### BACKGROUND OF THE INVENTION

1. Field of the Invention

The present invention relates generally to the conversion of light into electrical energy using solar (photovoltaic) cells that utilize a polymer-based material in place of silicon. More particularly, the present invention involves improving the conversion efficiency of plastic photovoltaic materials in order to provide a low cost and efficient plastic solar cell.

2. Description of Related Art

The publications and other reference materials referred to herein to describe the background of the invention and to provide additional detail regarding its practice are hereby incorporated by reference. For convenience, the reference materials are identified by author and grouped in the appended bibliography.

It is generally agreed that fossil fuels cannot last forever. The use of fossil fuels also causes serious environmental problems, such as the greenhouse effect, air pollution and acid rain, etc. Thus, there has been an extensive search for a clean, inexpensive and renewable energy source as an alternative to fossil fuels. One of the options is the solar cell, which converts sunlight to electricity. It is a renewable energy source and can be used as a power source at remote locations. Unfortunately, the cost of solar energy is still far above that of the traditional energy. For example, energy generated from present silicon solar cells costs from 20 to 25 cents per kilowatt-hour, compared to about 8 cents per kilowatt-hour for conventional sources. Therefore, it is crucial to improve the cost-effectiveness of photovoltaic systems. One approach to solving this problem has involved developing new materials to replace the relatively expensive silicon that is used in present solar cells. Organic (or polymer) materials have been proposed as potential candidates for use in developing solar cells into practical energy sources. The advantages of polymer (or plastic) materials include their excellent mechanical properties (flexibility), light weight and low cost. The use of polymers as the photovoltaic material will make it possible to fabricate lightweight, large-area devices at a relatively low cost.

Efficient photovoltaic cells should meet the following criteria: (a).the strong absorption of photons and creation of free carriers (electrons and holes) by photo excitation; and (b) a high efficiency of collecting of these free carriers. In organic semiconductors, photons are absorbed by an organic semiconductor which results in the creation of tightly bonded electron-hole pairs (excitons). This is in contrast to non-organic materials, such as silicon, where free electrons and holes are created. To collect the charges in organic semiconductors, exciton dissociation is required. It is known that exciton dissociation is efficient at interfaces between materials with a sufficient difference of electron affinities and ionization potentials. Often, the exciton dissociation can be as high as 100% in strong electron donor/acceptor systems. Therefore, the bottleneck of organic (polymer) solar cells is the carrier transport from the (p-n) interface to the metal electrodes.

Organic (polymer) materials suffer from low carrier mobility and short carrier lifetime. This prevents the carriers (electrons and holes) from traveling a long distance before capture by defects or traps. Typical carrier diffusion length is around a few nanometers for most organic (polymer) materials. This is far less than the typical thickness of solar cell layers that are around 100 nm. Hence the device thickness has to be decreased in order to increase the collection efficiency. Unfortunately, the decrease of device thickness significantly decreases the optical absorption as well as increases the complexity of device fabrication.

One of the major bottlenecks of current polymer (as well as organic) solar cells is their low carrier transport capability, which results in a rather low short-circuit current density. For solar cells, the conversion efficiency is mainly determined by the short-circuit current (Jsc) and the open-circuit voltage (Voc). In order to improve the device efficiency, a primary goal is to enhance the carrier transport of plastic solar cells so that the Jsc can be enhanced. FIG. 1 shows the I-V (current density vs. voltage) curves of the first small organic molecular photovoltaic cell demonstrated in 1986 whose efficiency was 1%. Compared to typical silicon solar cells, the Jsc (short-circuit current density) is about 30-40 times smaller. The power conversion efficiency under AM2 (75 mW/cm²) illumination is about 1%. By reducing the device thickness and modifying the work function of the anode, the Jsc of the latest organic solar cells have been improved to approximately 6 mA/cm². The power conversion efficiency is 3.6%. The improvement is limited by the poor carrier transport.

There is a present and continuing need to develop new polymer (plastic) photovoltaic materials that have improved conversion efficiency, are low cost and easy to fabricate into solar cells. Such materials are essential in order to provide a low-cost alternative to existing silicon solar cells.

### SUMMARY OF THE INVENTION

The present invention enhances the conversion efficiency of plastic (polymer) solar cells by improving the carrier transport of the polymer that is used as the photovoltaic material. In one example of the invention, we have doubled the efficiency of a plastic solar cell by adding a small amount of electrolyte to the polymer. This is mainly attributed to the improvement of carrier transport. However, the reasons for the improvement are not entirely known. In another example, we also found that the carrier transport in a polymer can be dramatically improved by selecting specific polymer morphologies. By combining these two aspects of the present invention, one is able to significantly improve the efficiency of current plastic solar cells. Judging by the current record of 2.5% conversion efficiency (demonstrated by Sariciftci et al.), a 5% efficiency is achievable in accordance with this invention. The present invention provides for the fabricating of efficient and stable plastic solar cells with a low-cost continuous polymer coating process.

The present invention involves making efficient plastic solar cells by improving their carrier transport capability by the following methods: (a) improving material conductivity by blending a small amount of electrolyte into the polymer films; (b) by fine tuning polymer morphology so that the carrier mobility increases. A 5% power efficiency can be achieved based on our preliminary results. This number (5%) is similar to or better than the efficiency achieved by amorphous silicon solar cells.

Our invention significantly enhances the Jsc of plastic solar cells. By adding a very small amount of ionic electrolyte into the plastic solar cells (0.01 to 5 percent by weight), it was discovered that the Jsc was doubled. Our invention is used with device structures that are typical polymer solar cells, consisting of a layer of polymer thin film sandwiched between a transparent anode (indium tin-oxide, ITO) and a cathode.

The above discussed and many other features and attendant advantages of the present invention will become better understood by reference to the detailed description when taken in conjunction with the accompanying drawings.

### BRIEF DESCRIPTION OF THE DRAWINGS

FIG. 1 is the I-V (current density—voltage) curves of the first efficient organic solar cell in 1986.

FIG. 2 is the I-V curves of MEH-PPV:C₆₀ devices under 120 mW/cm² white light illumination.

FIG. 3 is the I-V characteristics of MEH-PPV:C₆₀ (12.5 wt %) composite devices fabricated with xylene and tetrahydrofuran (THF).

FIG. 4 shows an example of a chemical structure of a PPV-derivative that is useful in photovoltaic application in accordance with the present invention.

FIG. 5 is the I-V curves of MEH-PPV:C₆₀ devices under illumination.

FIG. 6 is a graph of the short-circuit currents of devices in accordance with present the invention which have different amounts of polymer electrolyte. The short-circuit currents were measured under 80 mW/cm² white light illumination.

FIG. 7 is a schematic representation of an exemplary solar cell in accordance with the present invention.

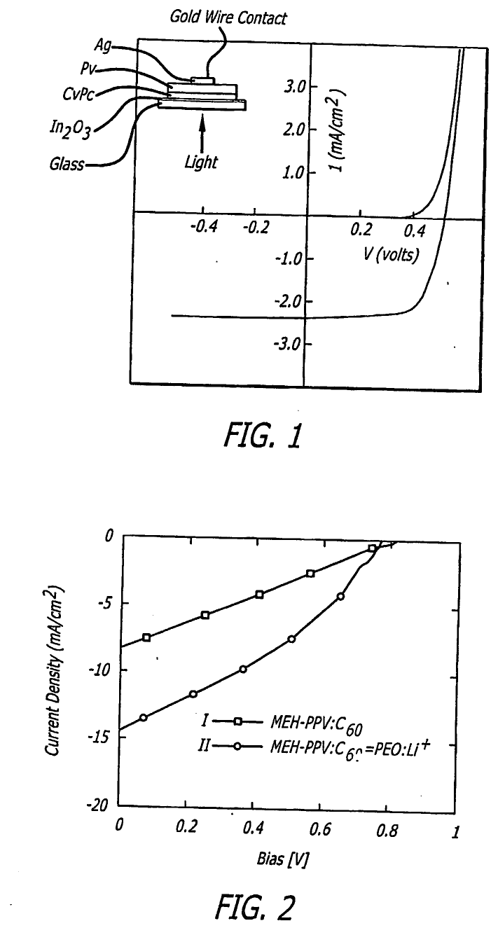

### DETAILED DESCRIPTION OF THE INVENTION

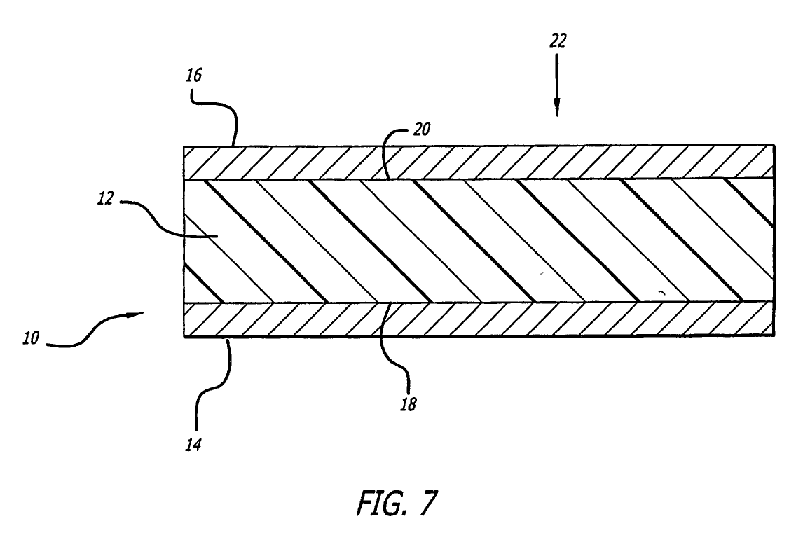

An exemplary solar cell in accordance with the present invention is shown generally at 10 in FIG. 7. The solar cell 10 includes an active material in the form of a photovoltaic film 12. The photovoltaic film 12 has a first side 20 and a second side 18. The photovoltaic film 12 is sandwiched between a transparent anode 16 and a cathode 14. Sunlight or light from another source passes through the transparent anode 16 as represented by arrow 22. The structure and use of the solar cell 10 is basically the same as existing solar cells that use organic materials as the photovoltaic film. The principal difference is that the active material provided in accordance with the present invention has a conversion efficiency that is much higher than was previously possible using organic materials. The active material in accordance with the present invention is a mixture of a semi-conducting polymer and an ionic electrolyte. The ionic electrolyte is present in the mixture in an amount ranging from 0.01 to 5 weight percent.

As is known in the art, the semi-conducting polymer is made up of a p-type polymer and an n-type electron acceptor. The present invention is mainly related to p-type semi-conducting polymers with various conductivity ranges. Examples include, but are not limited to, derivatives of poly(p-phenylene-vinylene) (PPV), polyfluorene (PF), and polythiophene (PT). The following list is exemplary. PPV derivatives: poly(2-methoxy-5-(2′-ethyl-hexyloxy)-1,4-phenylene vinylene) (MEH-PPV), poly(2-butoxy, 5-2′-ethyl-hexyloxy-p-phenylene vinylene) (BEH-PPV) and poly(2,5-bis-cheolestranoxy-1,4-phenylene vinylene) (BCHA-PPV); PF derivatives: poly(9,9-dioctylfluorene) (DOc-PF), poly(9,9′-dioctylfluorene-co-benzothiadiazole) (F8BT), and poly(9,9′-dioctylfluorene-co-bis-N,N′-(4-butylphenyl)-bis-N,N′-phenyl-1,4-phenylenediamine); and PT derivatives: poly(3-alkylthiophene) (PATs), poly(3-(4-octyl-phenyl)-2,2-bithiophene) (PTOPT), and poly(3-(4′-(1″,4″,7″-trioxaoctyl)thiophene) (PEOPT). Thiophene oligomers and thiophene dendrimers may also be used.

The possible electrochemical window of the polymer is usually defined as the first oxidation potential to the first reduction reaction potential of the polymer. For example, the peak reduction and oxidation potential of DOc-PF are −2.54V and +1.60V is Ag/AgCl, respectively. Therefore, the window of DOc-PF is about 4v. However, the window still depends on the individual property of the specific polymer.

The n-type electron acceptors can be any of the acceptors that have been used in solar cell applications. Exemplary n-type electron acceptors include cyano-PPV (PPV with —CN side groups), C₆₀, Carbon nano tubes, and organic compounds with strong electron withdrawing capability. C₆₀ is a preferred n-type electron acceptor. The relative amounts of p-type semi-conducting polymer and electron acceptor in the mixture may be varied depending upon the particular combination used. Reference to existing formulations may be made or routine experimentation may be used to establish the appropriate amounts of the two ingredients. In general, the p-type semi-conducting polymer will make up the majority of the mixture.

The ionic electrolyte is preferably an ionic salt. A preferred ionic salt is lithium salt, due to its high ionic conductivity. Exemplary lithium salts include LiCF₃SO₃, LiPF₆, LiAsF₆, LiSbF₆. However, other salts are also possible, such as lithium perchlorate, lithium triflate and lithium trifluoromethyl sulfonimide. The preferred amount of ionic electrolyte in the active material is from 0.2 to 2.5 weight percent. Active materials that contain about 1.0 weight percent ionic electrolyte are particularly preferred. The ionic electrolyte may be incorporated directly into the semi-conducting polymer mixture or it may be added as a polymeric ionic electrolyte. A polymeric ionic electrolyte is made by first combining the ionic electrolyte with a polymer that functions as a carrier for the ionic electrolyte. Suitable polymers for use in forming the polymeric ionic electrolyte include polyethylene oxide (PEO) and its derivatives as well as crown ether-containing compounds. Exemplary crown ethers include 18-crown-6, 15-crown-5 and 12-crown-4. The use of polymeric ionic electrolytes is preferred.

In order to prevent the phase separation between the semi-conducting polymer (such as MEH-PPV:C₆₀) and the ionic electrolyte polymer (such as PEO:Lithium salt), it is desirable to provide a polymer having both electrical and ionic conductivities. In such cases, the use of a polymeric ionic electrolyte is not necessarily required. One such example is BDOH-PF, which has been successfully applied on the light-emitting electrochemical cells. Alternatively, the use of a polymeric ionic electrolyte can be avoided by attaching the ionic electrolyte directly to the polymer chain of the semi-conducting polymer. FIG. 4 shows an example of a chemical structure of a PPV-derivative that is useful in photovoltaic applications in accordance with the present invention. In this chemical structure, n is more than 5 repeat units. This structure, and structures like it, attaches the ionic electrolyte directly to the polymer chain.

A preferred exemplary active material is an admixture of poly(2-methoxy-5-(2′-ethyl-hexyloxy)-1,4-phenylene vinylene) (MEH-PPV) and C₆₀. FIG. 2 shows the I-V curves of MEH-PPV:C₆₀ devices without an ionic electrolyte (Device I) and with an ionic electrolyte in the form of a polymeric ionic electrolyte (PEO:LiCF₃SO₃) (Device II). The light source is a 120 mW/cm² white light source. The open-circuit voltage (Voc) and the short-circuit current density (Jsc) for Device I are 0.83 V and 8.3 mA/cm², respectively. The fill factor (FF), which is defined as the maximum power (IV)ₘₐₓ divided by the product of Voc and Jsc, is around 0.26. The power conversion energy is thus calculated to be 1.5%. After adding the polymer electrolyte, where the weight ratio of active polymer layer is MEH-PPV:C₆₀:PEO:LiCF₃SO₃=3:1:0.25:0.05, it can be clearly seen that the Jsc of Device II increases to 14.4 mA/cm², a 73% increase. The fill factor was increased from 0.26 to 0.36, a 38% increase. The higher FF indicates that the addition of the ionic electrolyte has improved the charge transport. The amount of electrolyte may be varied provided that the desired level of power conversion is achieved without causing undue phase separation. It is worth mentioning that adding electrolyte into the polymer device was demonstrated by Pei et al. on polymer light-emitting electrochemical cells (LECs). LECs have achieved some of the best records in device efficiency. It was found by Pei and Yang that the control of phase separation (or morphology) between polymer and electrolyte plays a major role of determining device performance.

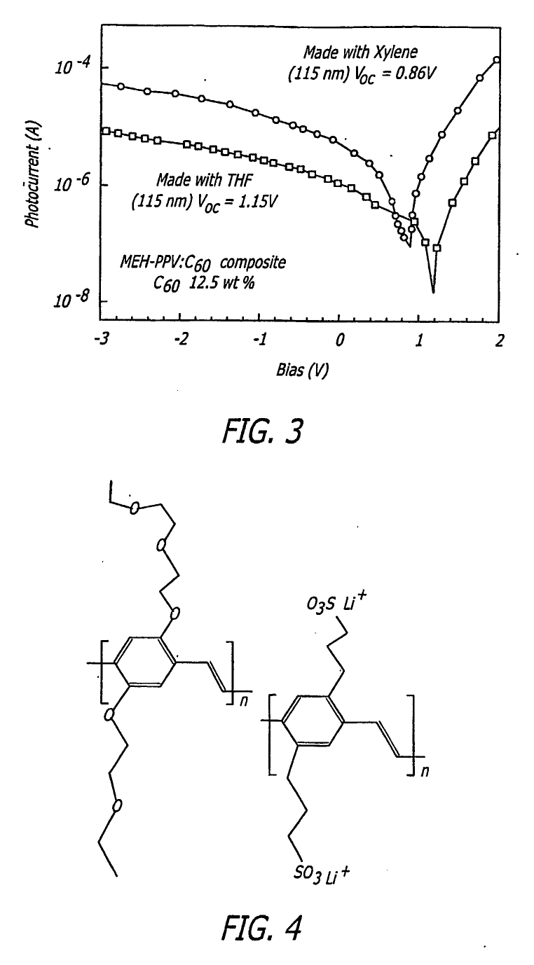

Polymer morphology also plays an important role in regular polymer electronic devices. We have demonstrated that the electronic and optical properties of the device are closely linked to the morphology of polymer thin films. The morphology can be manipulated by using different organic solvents, concentrations, spin speeds, and thermal annealing. The correlation between morphology and the performance of polymer light emitting diodes (PLED) has also been well established by our group (six papers were published within the last two years). Based on this knowledge, not only can optimized fabrication parameters be realized, but it is also possible to design better device structures. For example, it has been shown that the effects of post-annealing of polymer thin films significantly enhance the carrier injection in polymer diodes. Another example, shown in FIG. 3, demonstrates that the Voc of plastic solar cells can be manipulated simply by using different organic solvents that resulted in different polymer morphologies.

The anode and cathode between which the active material is sandwiched may be any of the anode/cathode combinations that have been used in polymer (plastic) solar cells. Indium tin oxide is widely used as the anode material and is preferred. The cathode may be made from any suitable metal or other electrically conductive material as is known in the art. Multiple layer or multiple element electrodes are typically utilized.

The procedures for fabricating the solar cells in accordance with the present invention are the same as the procedures used to make other thin polymer film solar cells. This generally involves spin coating of the semi-conducting polymer/ionic electrolyte mixture onto either the anode or cathode followed by application of the other electrode onto the exposed surface of the polymer film

Examples of practice are as follows:

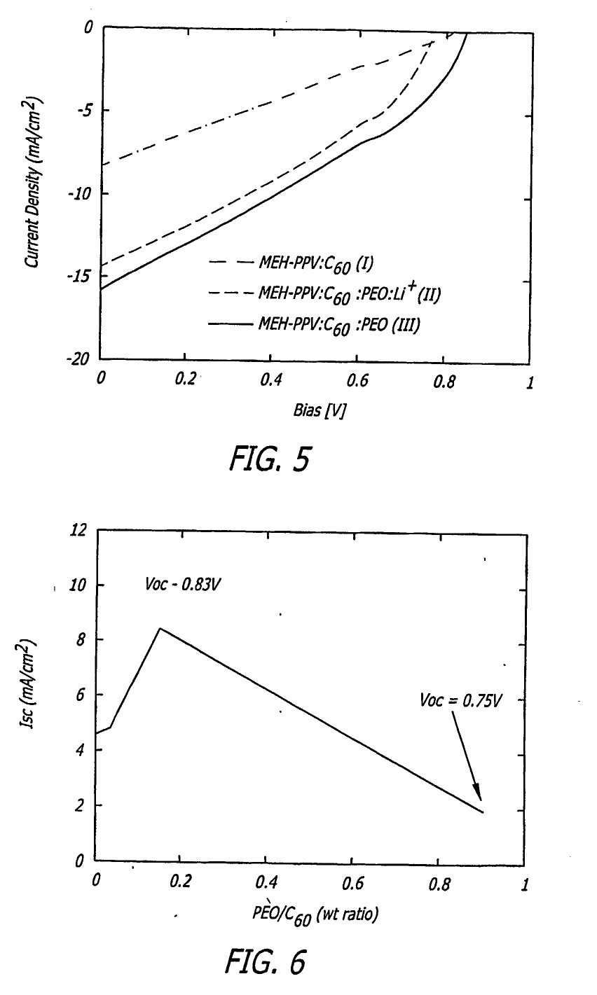

A photovoltaic device in accordance with the present invention was fabricated firstly by spin coating a MEH-PPV:C₆₀ blend (3:1 by weight) from 1,2-dichlorobenzene solution onto indium-tin oxide (ITO) glass substrates which were pre-coated with 80 nm 3,4-polyethylenedioxythiophene-polystyrenesulfonate (PEDOT). The resulting thickness of the composition polymer film was ˜0.1 μm. Then, the bilayer cathode consisting of 500 Å calcium overcoated by a 1000 Å aluminum was thermally evaporated onto the polymer film. For devices with polymer electrolyte, polyethylene oxide (PEO) and lithium trifluoromethanesulfate (LiCF₃SO₃) with a weight ratio of 5:1 in cyclohexanone was added into the MEH-PPV:C₆₀ blend prior to spin casting to form the active polymer layer. A tungsten lamp was used as the light source to measure the device photoresponse (see FIG. 5).

The effect of the concentration of PEO/Li⁺ in the active polymer blend on the Isc is illustrated in FIG. 6. The Isc increased firstly with the amount of PEO/Li⁺ and then went down when more polymeric ionic electrolyte was added. The optimized PEO concentration is around 20 wt % of C₆₀, which corresponds to 6.7 wt % of MEH-PPV and about 1 percent by weight LiCF₃SO₃. Meanwhile, Voc decreases with the amount of ionic electrolyte and drops to 0.75V as 90% of PEO/Li⁺ was added. Preferred ranges for the electrolyte are from 0.2 wt % to 2.5 wt %.

Based on our preliminary results and the 2.5% state-of-the-art plastic solar cell efficiency (as reported by other groups), we expect a 5% power conversion efficiency can be achieved using solar cells in accordance with the present invention. This relatively high conversion efficiency is significant to plastic solar cells and to the field of solar energy. By using solar cells in accordance with the present invention, the cost of solar energy will be dramatically reduced and the acceptance of solar energy will be much improved.

Having thus described exemplary embodiments of the present invention, it should be noted by those skilled in the art that the within disclosures are exemplary only and that various other alternatives, adaptations and modifications may be made within the scope of the present invention. Accordingly, the present invention is not limited to the above preferred embodiments and examples, but is only limited by the following claims.

### REFERENCES

1. Energy Information Administration, “Electricity Prices for Households,” http://www.eia.doe.gov/emeu/international/elecprih.html
2. J. J. M. Halls, C. A. Walsh, N. C. Greenham, E. A. Marseglia, R. H. Friend, S. C. Morattl, and A. B. Holmes, Nature, 376, 498 (1995).
3. C. W. Tang, Appl. Phys. Lett. 48, 183 (1986).
4. P. Peumans and S. R. Forrest, Appl. Phys. Lett. 79, 126 (2001)
5. G. Yu, J. Gao, J. C. Hummelen, F. Wudl, and A. J. Heeger, Science, 270, 1789 (1995).
6. Qibing Pei, Gang Yu, C. Z., Y. Yang and Alan J. Heeger, Science, 269, 1086 (1995).
7. Y. Yang and Qibing Pei, J. Appl. Phys., 81, 3294 (1997).
8. Y. Shi, J. Liu, and Y. Yang, J. Appl. Phys. 87, 4254 (2000).
9. J. Liu, Y. Shi, L. Ma, and Y. Yang, J. Appl. Phys. 88, 605 (2000).
10. J. Liu, T. F. Guo, and Y. Yang, J. Appl. Phys. 91, 1595 (2002).
11. J. Liu, Y. Shi, and Y. Yang, Adv. Funt. Mater. 11, 420 (2001).
12. T. F. Guo and Y. Yang, Appl. Phys. Lett., 80, 148 (2002).
13. S. E. Shaheen, C. J. Brabee, N. S. Sariciftci, F. Padinger, T. Fromherz, J. C. Hummelen, Appl. Phys. Lett. 78, 841 (2001).

1. A composition of matter that is adapted for use in a solar cell, said composition of matter comprising a mixture of a semi-conducting polymer and an ionic electrolyte wherein said semi-conducting polymer comprises a p-type polymer and an n-type electron acceptor and said ionic electrolyte is present in said mixture in an amount ranging from 0.01 to 5 weight percent.

2. A composition of matter according to claim 1 wherein said semi-conducting polymer is selected from the group consisting of poly(p-phenylene-vinylene) derivatives, polyfluorene derivatives and polythiophene derivatives.

3. A composition of matter according to claim 2 wherein said poly(p-phenylene-vinylene derivative is selected from the group consisting of poly(2-methoxy-5-(2′-ethyl-hexyloxy)-1,4-phenylene vinylene), poly(2-butoxy, 5-2′-ethyl-hexyloxy-p-phenylene vinylene) and poly(2,5-bis-cheolestranoxy-1,4-phenylene vinylene).

4. A composition of matter according to claim 2 wherein said polyflouorene derivative is selected from the group consisting of poly(9,9-dioctylfluorene), poly(9,9′-dioctylfluorene-co-benzothiadiazole), and poly(9,9′-dioctylfluorene-co-bis-N,N′-(4-butylphenyl)-bis-N,N′-phenyl-1,4-phenylenediamine).

5. A composition of matter according to claim 2 wherein said polythiophene derivative is selected from the group consisting of poly(3-alkylthiophene), poly(3-(4-octyl-phenyl)-2,2-bithiophene and poly(3-(4′-(1″,4″,7″-trioxaoctyl)thiophene).

6. A composition of matter according to claim 3 wherein said poly(p-phenylene-vinylene derivative is poly(2-methoxy-5-(2′-ethyl-hexyloxy)-1,4-phenylene vinylene).

7. A composition of matter according to claim 1 wherein said n-type electron acceptor is selected from the group consisting of C₆₀, cyano-poly(p-phenylene-vinylene) and carbon nano tubes.

8. A composition of matter according to claim 7 wherein said n-type electron acceptor is C₆₀.

9. A composition of matter according to claim 6 wherein said n-type electron acceptor is C₆₀.

10. A composition of matter according to claim 1 wherein said ionic electrolyte is selected from the group consisting of LiCF₃SO₃, LiPF₆, LiAsF₆, LiSbF₆, lithium perchlorate, lithium triflate and lithium trifluoromethyl sulfonimide.

11. A composition of matter according to claim 10 wherein said ionic electrolyte is LiCF₃SO₃.

12. A composition of matter according to claim 9 wherein said ionic electrolyte is LiCF₃SO₃.

13. A composition of matter according to claim 1 wherein the amount of said ionic electrolyte present in said mixture ranges from 0.2 to 2.5 percent by weight.

14. A composition of matter according to claim 1 wherein said ionic electrolyte is a polymeric ionic electrolyte that comprises said ionic electrolyte in combination with a polymer selected from the group consisting of polyethylene oxide and crown ether-containing compounds.

15. A composition of matter according to claim 14 wherein said polymeric ionic electrolyte comprises said ionic electrolyte in combination with polyethylene oxide.

16. A composition of matter according to claim 15 wherein said p-type polymer is poly(2-methoxy-5-(2′-ethyl-hexyloxy)-1,4-phenylene vinylene), said n-type electron acceptor is C₆₀ and said ionic electrolyte is LiCF₃SO₃.

17. A composition of matter according to claim 16 wherein the amount of ionic electrolyte present in said mixture is between 0.2 and 2.5 weight percent.

18. A composition of matter according to claim 17 wherein the amount of ionic electrolyte present in said mixture is about 1 weight percent.

19. A solar cell for use in converting sunlight into electricity, said solar cell comprising:
a composition of matter according to claim 1 that is in the form of a photovoltaic film having a first side and a second side;
an anode located on the first side of said photovoltaic film; and
a cathode located on the second side of said photovoltaic film.

20. A solar cell according to claim 19 wherein said semi-conducting polymer is selected from the group consisting of poly(p-phenylene-vinylene) derivatives, polyfluorene derivatives and polythiophene derivatives.

21. A solar cell according to claim 20 wherein said poly(p-phenylene-vinylene derivative is selected from the group consisting of poly(2-methoxy-5-(2′-ethyl-hexyloxy)-1,4-phenylene vinylene), poly(2-butoxy, 5-2′-ethyl-hexyloxy-p-phenylene vinylene) and poly(2,5-bis-cheolestranoxy-1,4-phenylene vinylene).

22. A solar cell according to claim 20 wherein said polyflouorene derivative is selected from the group consisting of poly(9,9-dioctylfluorene), poly(9,9′-dioctylfluorene-co-benzothiadiazole), and poly(9,9′-dioctylfluorene-co-bis-N,N′-(4-butylphenyl)-bis-N,N′-phenyl-1,4-phenylenediamine).

23. A solar cell according to claim 20 wherein said polythiophene derivative is selected from the group consisting of poly(3-alkylthiophene), poly(3-(4-octyl-phenyl)-2,2-bithiophene), and poly(3-(4′-(1″,4″,7″-trioxaoctyl)thiophene).

24. A solar cell according to claim 21 wherein said poly(-phenylene-vinylene derivative is poly(2-methoxy-5-(2′-ethyl-hexyloxy)-1,4-phenylene vinylene).

25. A solar cell according to claim 19 wherein said n-type electron acceptor is selected from the group consisting of C₆₀, cyano-poly(p-phenylene-vinylene) and carbon nano tubes.

26. A solar cell according to claim 25 wherein said n-type electron acceptor is C₆₀.

27. A solar cell according to claim 24 wherein said n-type electron acceptor is C₆₀.

28. A solar cell according to claim 19 wherein said ionic electrolyte is selected from the group consisting of LiCF₃SO₃, LiPF₆, LiAsF₆, LiSbF₆, lithium perchlorate, lithium triflate and lithium trifluoromethyl sulfonimide.

29. A solar cell according to claim 28 wherein said ionic electrolyte is LiCF₃SO₃.

30. A solar cell according to claim 27 wherein said ionic electrolyte is LiCF₃SO₃.

31. A solar cell according to claim 19 wherein the amount of said ionic electrolyte present in said mixture ranges from 0.2 to 2.5 percent by weight.

32. A solar cell according to claim 19 wherein said ionic electrolyte is a polymeric ionic electrolyte that comprises said ionic electrolyte in combination with a polymer selected from the group consisting of polyethylene oxide and crown ether-containing compounds.

33. A solar cell according to claim 32 wherein said polymeric ionic electrolyte comprises said ionic electrolyte in combination with polyethylene oxide.

34. A solar cell according to claim 33 wherein said p-type polymer is poly(2-methoxy-5-(2′-ethyl-hexyloxy)-1,4-phenylene vinylene), said n-type electron acceptor is C₆₀ and said ionic electrolyte is LiCF₃SO₃.

35. A solar cell according to claim 34 wherein the amount of ionic electrolyte present in said mixture is between 0.2 and 2.5 weight percent.

36. A solar cell according to claim 35 wherein the amount of ionic electrolyte present in said mixture is about 1 weight percent.

37. A method for making a solar cell comprising the steps of:
providing a composition of matter according to claim 1 that is in the form of a photovoltaic film having a first side and a second side;
placing an anode on the first side of said photovoltaic film wherein said anode is in electrical contact with said photovoltaic film; and
placing a cathode on the second side of said photovoltaic film wherein said cathode is in electrical contact with said photovoltaic film.

38. A method for making a solar cell according to claim 37 wherein said semi-conducting polymer is selected from the group consisting of poly(p-phenylene-vinylene) derivatives, polyfluorene derivatives and polythiophene derivatives.

39. A method for making a solar cell according to claim 38 wherein said poly(p-phenylene-vinylene derivative is selected from the group consisting of poly(2-methoxy-5-(2′-ethyl-hexyloxy)-1,4-phenylene vinylene), poly(2-butoxy, 5-2′-ethyl-hexyloxy-p-phenylene vinylene) and poly(2,5-bis-cheolestranoxy-1,4-phenylene vinylene).

40. A method for making a solar cell according to claim 38 wherein said polyflouorene derivative is selected from the group consisting of poly(9,9-dioctylfluorene), poly(9,9′-dioctylfluorene-co-benzothiadiazole), and poly(9,9′-dioctylfluorene-co-bis-N,N′-(4-butylphenyl)-bis-N,N′-phenyl-1,4-phenylenediamine).

41. A method for making solar cell according to claim 38 wherein said polythiophene derivative is selected from the group consisting of poly(3-alkylthiophene), poly(3-(4-octyl-phenyl)-2,2-bithiophene), and poly(3-(4′-(1″,4″,7″-trioxaoctyl)thiophene).

42. A method for making a solar cell according to claim 39 wherein said poly(p-phenylene-vinylene derivative is poly(2-methoxy-5-(2′-ethyl-hexyloxy)-1,4-phenylene vinylene).

43. A method for making a solar cell according to claim 37 wherein said n-type electron acceptor is selected from the group consisting of C₆₀, cyano-poly(p-phenylene-vinylene) and carbon nano tubes.

44. A method for making a solar cell according to claim 43 wherein said n-type electron acceptor is C₆₀.

45. A method for making a solar cell according to claim 42 wherein said n-type electron acceptor is C₆₀.

46. A method for making a solar cell according to claim 37 wherein said ionic electrolyte is selected from the group consisting of LiCF₃SO₃, LiPF₆, LiAsF₆, LiSbF₆, lithium perchlorate, lithium triflate and lithium trifluoromethyl sulfonimide.

47. A method for making a solar cell according to claim 46 wherein said ionic electrolyte is LiCF₃SO₃.

48. A method for making a solar cell according to claim 45 wherein said ionic electrolyte is LiCF₃SO₃.

49. A method for making a solar cell according to claim 37 wherein the amount of said ionic electrolyte present in said mixture ranges from 0.2 to 2.5 percent by weight.

50. A method for making a solar cell according to claim 37 wherein said ionic electrolyte is a polymeric ionic electrolyte that comprises said ionic electrolyte in combination with a polymer selected from the group consisting of polyethylene oxide and crown ether-containing compounds.

51. A method for making a solar cell according to claim 50 wherein said ionic electrolyte comprises said ionic electrolyte in combination with polyethylene oxide.

52. A method for making a solar cell according to claim 51 wherein said p-type polymer is poly(2-methoxy-5-(2′-ethyl-hexyloxy)-1,4-phenylene vinylene), said n-type electron acceptor is C60 and said ionic electrolyte is LiCF₃SO₃.

53. A method for making a solar cell according to claim 52 wherein the amount of ionic electrolyte present in said mixture is between 0.2 and 2.5 weight percent.

54. A method for making a solar cell according to claim 53 wherein the amount of ionic electrolyte present in said mixture is about 1 weight percent.

55. A method for converting sunlight into electricity comprising the steps of:
providing a solar cell according to claim 37;
exposing said solar cell to sufficient sunlight to generate an electrical potential between said anode and said cathode.

56. A method for converting sunlight into electricity according to claim 55 wherein said semi-conducting polymer is selected from the group consisting of poly(p-phenylene-vinylene) derivatives, polyfluorene derivatives and polythiophene derivatives.

57. A method for converting sunlight into electricity according to claim 56 wherein said poly(p-phenylene-vinylene derivative is selected from the group consisting of poly(2-methoxy-5-(2′-ethyl-hexyloxy)-1,4-phenylene vinylene), poly(2-butoxy, 5-2′-ethyl-hexyloxy-p-phenylene vinylene) and poly(2,5-bis-cheolestranoxy-1,4-phenylene vinylene).

58. A method for converting sunlight into electriicty according to claim 56 wherein said polyflouorene derivative is selected from the group consisting of poly(9,9-dioctylfluorene), poly(9,9′-dioctylfluorene-co-benzothiadiazole), and poly(9,9′-dioctylfluorene-co-bis-N,N′-(4-butylphenyl)-bis-N,N′-phenyl-1,4-phenylenediamine).

59. A method for converting sunlight into electricity according to claim 56 wherein said polythiophene derivative is selected from the group consisting of poly(3-alkylthiophene), poly(3-(4-octyl-phenyl)-2,2-bithiophene), and poly(3-(4′-(1″,4″,7″-trioxaoctyl)thiophene).

60. A method for converting sunlight into electricity according to claim 57 wherein said poly(p-phenylene-vinylene derivative is poly(2-methoxy-5-(2′-ethyl-hexyloxy)-1,4-phenylene vinylene).

61. A method for converting sunlight into electricity according to claim 55 wherein said n-type electron acceptor is selected from the group consisting of C₆₀, cyano-poly(p-phenylene-vinylene) and carbon nano tubes.

62. A method for converting sunlight into electricity according to claim 61 wherein said n-type electron acceptor is C₆₀.

63. A method for converting sunlight into electricity according to claim 60 wherein said n-type electron acceptor is C₆₀.

64. A method for converting sunlight into electricity according to claim 55 wherein said ionic electrolyte is selected from the group consisting of LiCF₃SO₃, LiPF₆, LiAsF₆, LiSbF₆, lithium perchlorate, lithium triflate and lithium trifluoromethyl sulfonimide.

65. A method for converting sunlight into electricity according to claim 64 wherein said ionic electrolyte is LiCF₃SO₃.

66. A method for converting sunlight into electricity according to claim 63 wherein said ionic electrolyte is LiCF₃SO₃.

67. A method for converting sunlight into electricity according to claim 55 wherein the amount of said ionic electrolyte present in said mixture ranges from 0.2 to 2.5 percent by weight.

68. A method for converting sunlight into electricity according to claim 55 wherein said ionic electrolyte is a polymeric ionic electrolyte that comprises said ionic electrolyte in combination with a polymer selected from the group consisting of polyethylene oxide and crown ether-containing compounds.

69. A method for converting sunlight into electricity according to claim 68 wherein said polymeric ionic electrolyte comprises said ionic electrolyte in combination with polyethylene oxide.

70. A method for converting sunlight into electricity according to claim 69 wherein said p-type polymer is poly(2-methoxy-5-(2′-ethyl-hexyloxy)-1,4-phenylene vinylene), said n-type electron acceptor is C60 and said ionic electrolyte is LiCF₃SO₃.

71. A method for converting sunlight into electricity according to claim 70 wherein the amount of ionic electrolyte present in said mixture is between 0.2 and 2.5 weight percent.

72. A method for converting sunlight into electricity according to claim 54 wherein the amount of ionic electrolyte present in said mixture is about 1 weight percent.
